(19) United States
(12) Patent Application Publication
(10) Pub. No.: US 2025/0089190 A1
(43) Pub. Date: Mar. 13, 2025

(54) BOLTLESS ELECTRICAL HEADER ASSEMBLIES

(71) Applicant: FORD GLOBAL TECHNOLOGIES, LLC, Dearborn, MI (US)

(72) Inventor: Michael Terrence Zitkovic, JR., Dearborn, MI (US)

(21) Appl. No.: 18/462,541

(22) Filed: Sep. 7, 2023

(51) Int. Cl. H05K 5/02; H05K 5/06

(52) U.S. Cl. CPC H05K 5/0247; H05K 5/069; B60R 16/02

(57) ABSTRACT

Electrical header assemblies are provided for a sealed enclosure of an electrical component. An exemplary electrical header assembly may provide a boltless design that does not require the use of bolts, screws, adhesives, etc. for securing the electrical header assembly relative to the sealed enclosure. The electrical header assembly may include an electrical header and an electrical header connector for connecting the electrical header relative to the sealed enclosure. The electrical header may include a locking tang, and the electrical header connector may include a flared lip. The locking tang and the flared lip may be configured to engage one another to secure the electrical header to the electrical header connector as the electrical header is moved into engagement with the electrical header connector.

### TECHNICAL FIELD

This disclosure relates generally to the attachment of electrical headers to a sealed enclosure, and more particularly to electrical header assemblies that do not require bolts or other fasteners for securing the electrical header relative to the sealed enclosure.

### BACKGROUND

Many electrical components, such as traction battery packs, for example, require a gas-tight enclosure. Attaching an electrical header to the gas-tight enclosure typically requires various fasteners and sealing arrangements.

### SUMMARY

An electrical header assembly according to an exemplary aspect of the present disclosure includes, among other things, an electrical header including a first mounting flange having a locking tang, and an electrical header connector including a second mounting flange having a flared lip. The locking tang and the flared lip are configured to engage one another to secure the electrical header to the electrical header connector as the electrical header is moved into engagement with the electrical header connector.

In a further non-limiting embodiment of the foregoing electrical header assembly, the first mounting flange is disk-shaped and includes a front surface, a rear surface, and a circumferential surface that connects between the front surface and the rear surface.

In a further non-limiting embodiment of either of the foregoing electrical header assemblies, the locking tang is formed within the circumferential surface.

In a further non-limiting embodiment of any of the foregoing electrical header assemblies, a recess is formed in the rear surface.

In a further non-limiting embodiment of any of the foregoing electrical header assemblies, a first seal is received within the recess and arranged to seal against the flared lip.

In a further non-limiting embodiment of any of the foregoing electrical header assemblies, a second seal is arranged to seal against a cylindrical body of the second mounting flange.

In a further non-limiting embodiment of any of the foregoing electrical header assemblies, the locking tang is configured to flex outwardly to accommodate the flared lip within a slot of the first mounting flange as the electrical header is moved into further engagement with the electrical header connector.

In a further non-limiting embodiment of any of the foregoing electrical header assemblies, the flared lip is configured to engage a cam surface of the locking tang to force the locking tang to flex outwardly.

In a further non-limiting embodiment of any of the foregoing electrical header assemblies, the cam surface includes a lower plateau, an upper plateau, and an angled surface that connects between the lower plateau and the upper plateau.

In a further non-limiting embodiment of any of the foregoing electrical header assemblies, the flared lip enters the slot at the lower plateau and forces the locking tang to flex further outwardly as it travels along the angled surface toward the upper plateau as the electrical header is moved into further engagement with the electrical header connector.

An electrical component according to another exemplary aspect of the present disclosure includes, among other things, a sealed enclosure, an electrical header assembly including an electrical header, and an electrical header connector configured for mounting the electrical header relative to a wall of the sealed enclosure. The electrical header includes a first mounting flange having a locking tang, and the electrical header connector includes a second mounting flange having a flared lip that can engage the locking tang to secure the electrical header to the electrical header connector as the electrical header is moved into engagement with the electrical header connector.

In a further non-limiting embodiment of the foregoing electrical component, the electrical component is a traction battery pack.

In a further non-limiting embodiment of either of the foregoing electrical components, the second mounting flange of the electrical header connector includes a base.

In a further non-limiting embodiment of any of the foregoing electrical components, the base is integrated as part of the wall of the sealed enclosure.

In a further non-limiting embodiment of any of the foregoing electrical components, the base is mounted to the wall by a weld.

In a further non-limiting embodiment of any of the foregoing electrical components, the first mounting flange is disk-shaped and includes a front surface, a rear surface, and a circumferential surface that connects between the front surface and the rear surface.

In a further non-limiting embodiment of any of the foregoing electrical components, the locking tang is formed within the circumferential surface.

In a further non-limiting embodiment of any of the foregoing electrical components, a recess is formed in the rear surface. A first seal is received within the recess and arranged to seal against the flared lip.

In a further non-limiting embodiment of any of the foregoing electrical components, a second seal is arranged to seal against a cylindrical body of the second mounting flange.

In a further non-limiting embodiment of any of the foregoing electrical components, the locking tang is configured to flex outwardly to accommodate the flared lip within a slot of the first mounting flange as the electrical header is moved into further engagement with the electrical header connector.

The embodiments, examples, and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 illustrates select portions of an electrical component having a sealed enclosure. An electrical header assembly is mounted relative to the sealed enclosure.

FIG. 2 is a top view of an electrical header assembly.

FIG. 3 is a cross-sectional view through section 3-3 of the electrical header assembly of FIG. 2.

FIG. 4 is a cross-sectional view through section 4-4 of the electrical header assembly of FIG. 2.

FIG. 5 is a top view of an electrical header of an electrical header assembly.

FIG. 6 is a cross-sectional view through section 6-6 of the electrical header of FIG. 5.

FIG. 7 is a top view of an electrical header connector of an electrical header assembly.

FIG. 8 is a cross-sectional view through section 8-8 of the electrical header connector of FIG. 7.

FIG. 9 illustrates another exemplary sealed enclosure having an electrical header assembly mounted thereto.

FIG. 10 illustrates a traction battery pack that includes an electrical header assembly attached thereto.

FIG. 11 is a cross-sectional view of the traction battery pack of FIG. 10.

FIG. 12 illustrates an electrified vehicle that includes the traction battery pack of FIGS. 10 and 11.

### DETAILED DESCRIPTION

This disclosure details electrical header assemblies for a sealed electrical enclosure. An exemplary electrical header assembly may provide a boltless design that does not require the use of bolts, screws, adhesives, etc. for securing the electrical header assembly relative to the sealed enclosure. The electrical header assembly may include an electrical header and an electrical header connector for connecting the electrical header relative to the sealed enclosure. The electrical header may include a locking tang, and the electrical header connector may include a flared lip. The locking tang and the flared lip may be configured to engage one another to secure the electrical header to the electrical header connector as the electrical header is moved into engagement with the electrical header connector. These and other features are discussed in greater detail in the following paragraphs of this detailed description.

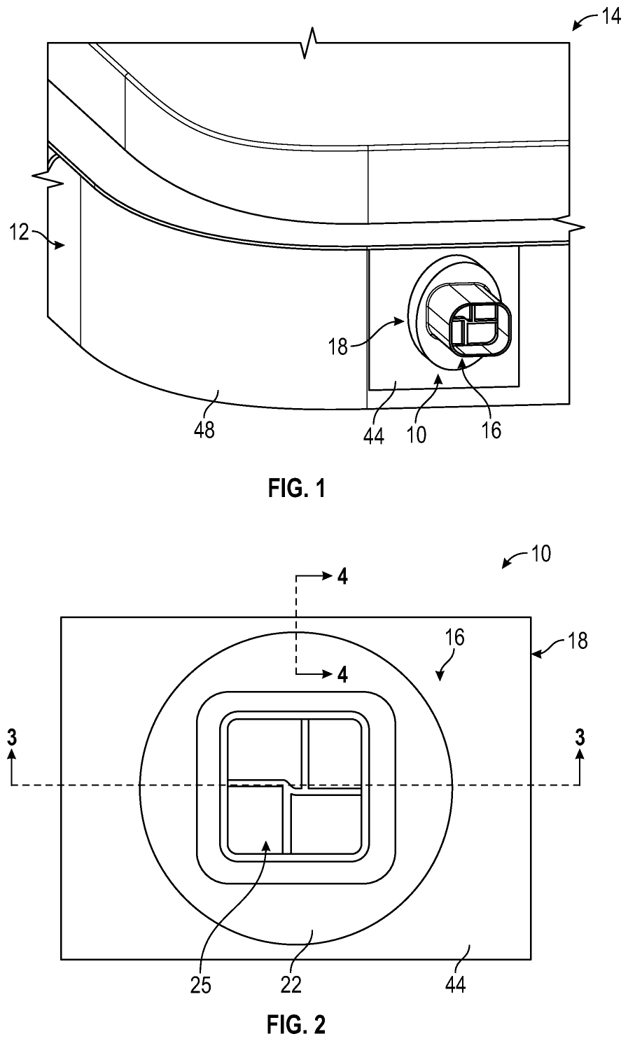

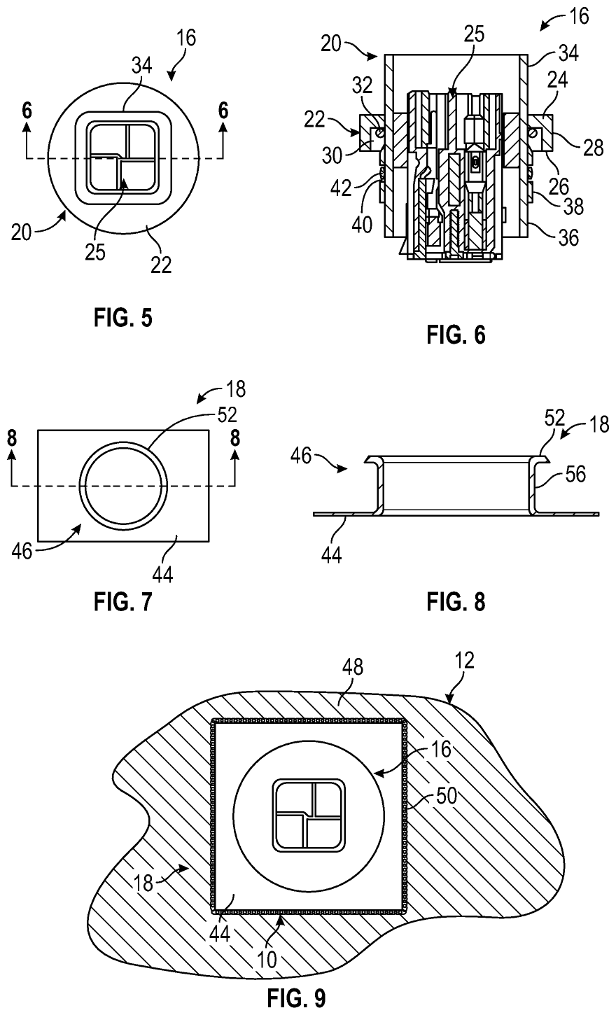

FIGS. 1-8 illustrate various aspects of an electrical header assembly 10 that may be secured to a sealed enclosure 12 of an electrical component 14. FIG. 1 illustrates the electrical header assembly 10 attached to the sealed enclosure 12, and FIGS. 2-8 illustrate the electrical header assembly 10 and its constituent components separate from the sealed enclosure 12.

The electrical header assembly 10 may provide a receptacle for receiving a wiring harness or other connector (not shown), such as for facilitating the connection of the electrical component 14 to another electrical component, for example. The sealed enclosure 12 could establish an outer housing of an automotive component or any other type of electrical component that requires a sealed enclosure.

Although a single electrical header assembly 10 is shown relative to the sealed enclosure 12 in the illustrated embodiment, the electrical component 14 could include a greater number of electrical header assemblies 10 within the scope of this disclosure. As further discussed below, the electrical header assembly 10 may provide a boltless design that does not require the use of bolts, screws, adhesives, etc. for securing the electrical header assembly 10 relative to the sealed enclosure 12.

The electrical header assembly 10 may include an electrical header 16 and an electrical header connector 18. The electrical header connector 18 is configured to facilitate the connection of the electrical header 16 relative to the sealed enclosure 12.

The electrical header 16 may include a housing 20 and an electrical contact assembly 25 held within the housing 20. The electrical contact assembly 25 may include, among other things, conductive contacts, busbars, pins, etc. for establishing an electrical connection when a wiring harness or other connector is secured to the electrical header 16.

The housing 20 of the electrical header 16 may include a mounting flange 22. The mounting flange 22 may be disk-shaped and may include a front surface 24, a rear surface 26, and a circumferential surface 28 that connects between the front surface 24 and the rear surface 26. When the electrical header 16 is mounted relative to the sealed enclosure 12, the rear surface 26 may face inwardly toward the sealed enclosure 12, and the front surface 24 may face outwardly in a direction away from the sealed enclosure 12.

A recess 30 may be formed in the rear surface 26. The recess 30 may extend in a direction from the rear surface 26 toward the front surface 24. A first seal 32 may be positioned within the recess 30. In an embodiment, the first seal 32 is a gasket seal. However, other types of seals could be accommodated within the recess 30.

A first housing section 34 of the housing 20 may protrude in a first direction away from the mounting flange 22, and a second housing section 36 of the housing 20 may protrude in a second direction away from the mounting flange 22. In a mounted position of the electrical header 16, the second housing section 36 is located between the mounting flange 22 and the sealed enclosure 12.

A ribbed section 38 of the housing 20 may extend radially outwardly of the second housing section 36. A groove 40 may be formed in the ribbed section 38. A second seal 42 may be positioned within the groove 40. In an embodiment, the second seal 42 is an o-ring seal. However, other types of seals could be accommodated within the groove 40.

The electrical header connector 18 may include a base 44 and a mounting flange 46. The mounting flange 46 may include a cylindrical body 56 that protrudes outwardly from the base 44. In an embodiment, the base 44 and the mounting flange 46 are formed together to provide a single piece, monolithic design. Stated another way, the mounting flange 46 is not mechanically joined to the base 44 in order to provide the electrical header connector 18.

The mounting flange 46 of the electrical header connector 18 may include a flared lip 52 located at a distal tip of the cylindrical body 56. As further discussed below, the flared lip 52 may interface with locking features of the mounting flange 22 of the electrical header 16 for securing the electrical header 16 to the electrical header connector 18 and thus mounting the electrical header 16 relative to the sealed enclosure 12.

In an embodiment, the base 44 of the electrical header connector 18 is integrated as part of a wall 48 of the sealed enclosure 12 (see, e.g., FIG. 1). In such an embodiment, the mounting flange 46 may be a draw formed feature of the wall 48 of the sealed enclosure 12.

In another embodiment, the base 44 may be a separate component that is secured to the wall 48 of the sealed enclosure 12. In such an embodiment, the base 44 may be secured to the wall 48 by one or more welds 50 (see FIG. 9).

Both the wall 48 of the sealed enclosure 12 and the electrical header connector 18 may be constructed from the same material. In an embodiment, the wall 48 and the electrical header connector 18 are each made from a metallic material, such as steel or aluminum, for example. The housing 20 of the electrical header 16 may be made of a plastic material.

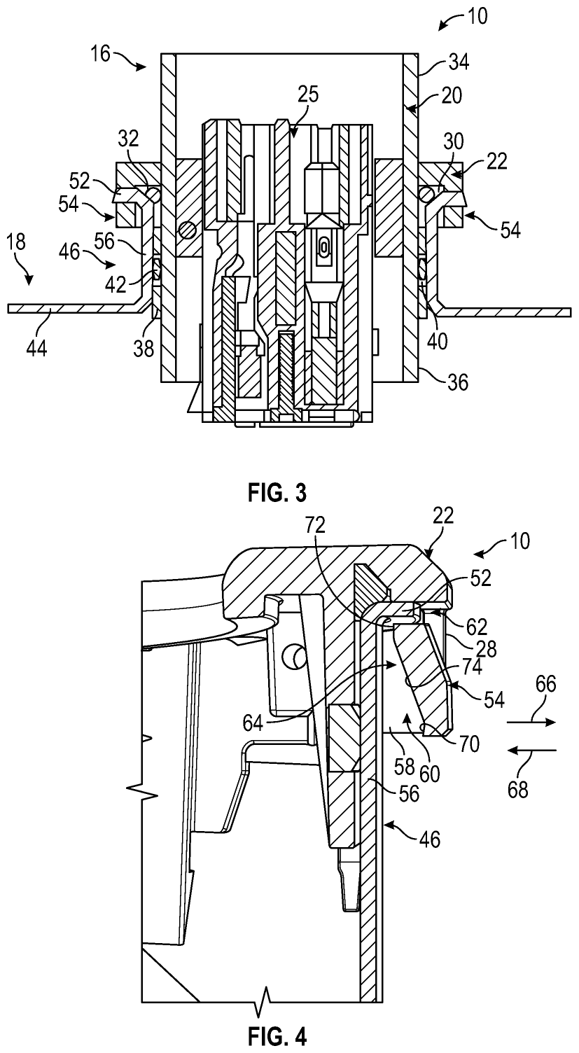

Referring now primarily to FIGS. 3 and 4, the electrical header 16 and the electrical header connector 18 may cooperate to establish a press-in-place design for connecting the electrical header 16 to the electrical header connector 18, and thus to the sealed enclosure 12, without using any bolts, screws, adhesives, etc. In this regard, the mounting flange 22 of the housing 20 of the electrical header 16 may include two or more locking tangs 54. Each locking tang 54 may be adapted for engaging the flared lip 52 of the electrical header connector 18 to secure the electrical header 16 relative to the wall 48 of the sealed enclosure 12. The locking tangs 54 may be formed within the circumferential surface 28 of the mounting flange 22. The total number of locking tangs 54 provided within the circumferential surface 28 of the mounting flange 22 is not intended to limit this disclosure.

Each locking tang 54 may be configured to engage the flared lip 52 of the mounting flange 46 as the electrical header 16 is moved toward the electrical header connector 18. For example, as the electrical header 16 is pushed into the mounting flange 46 of the electrical header connector 18, the flared lip 52 may enter a first section 58 of a slot 60 provided by the locking tang 54. Further, as the electrical header 16 is moved further toward the mounting flange 46, the flared lip 52 may engage a cam surface 64 of the locking tang 54, thereby forcing the locking tang 54 to flex outwardly in a direction of arrow 66. The outward movement of the locking tang 54 permits the flared lip 52 to enter into a second section 62 of the slot 60. The second section 62 may extend along an axis that is transverse to the first section 58. The locking tang 54 may flex inwardly in a direction of arrow 68 to return to its original unbiased position for locking the engaged position of the flared lip 52 when the flared lip 52 is received within the second section 62 of the slot 60. The electrical header 16 may therefore be considered fully mounted to the electrical header connector 18 once the flared lip 52 is positioned within the second section 62 of the slot 60.

The cam surface 64 of the locking tang 54 may be configured to gradually engage the flared lip 52 as the electrical header 16 is moved further into engagement with the electrical header connector 18. For example, the cam surface 64 may include a lower plateau 70, an upper plateau 72, and an angled surface 74 that extends from the lower plateau 70 to the upper plateau 72. The lower plateau 70 may be positioned further from the second section 62 of the slot 60 compared to the upper plateau 72. The angled surface 74 may be angled in a direction toward the center of the electrical header 16. During assembly, the flared lip 52 may enter the first section 58 of the slot 60 at the lower plateau 70 before engaging the angled surface 74. The engagement force between the locking tang 54 and the flared lip 52 may increase as the electrical header 16 is moved further toward the base 44 of the electrical header connector 18, thus causing the locking tang 54 to flex further outwardly as the flared lip 52 inches closer to the upper plateau 72. Subsequently, after clearing the upper plateau 72, the flared lip 52 may enter the second section 62 of the slot 60 to fully secure the electrical header 16 to the electrical header connector 18.

In the assembled condition, the first seal 32 may be arranged to seal against the flared lip 52 of the mounting flange 46 of the electrical header connector 18, and the second seal 42 may be arranged to seal against the cylindrical body 56 of the mounting flange 46. Together, the first seal 32 and the second seal 42 provide sealing redundancy, thereby limiting or even preventing corrosion inducing substances (e.g., moisture, salt, etc.) from entering an interior area of the sealed enclosure 12 through the electrical header assembly 10.

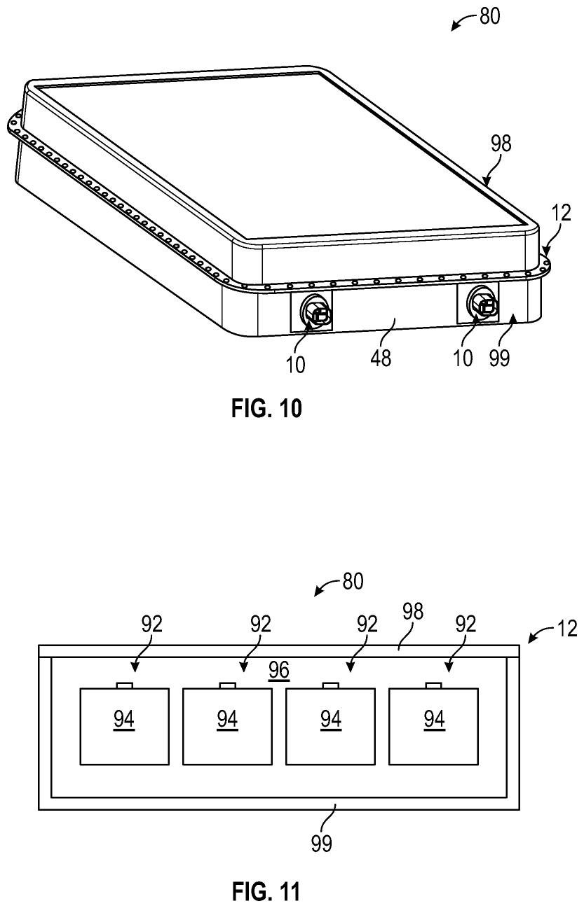

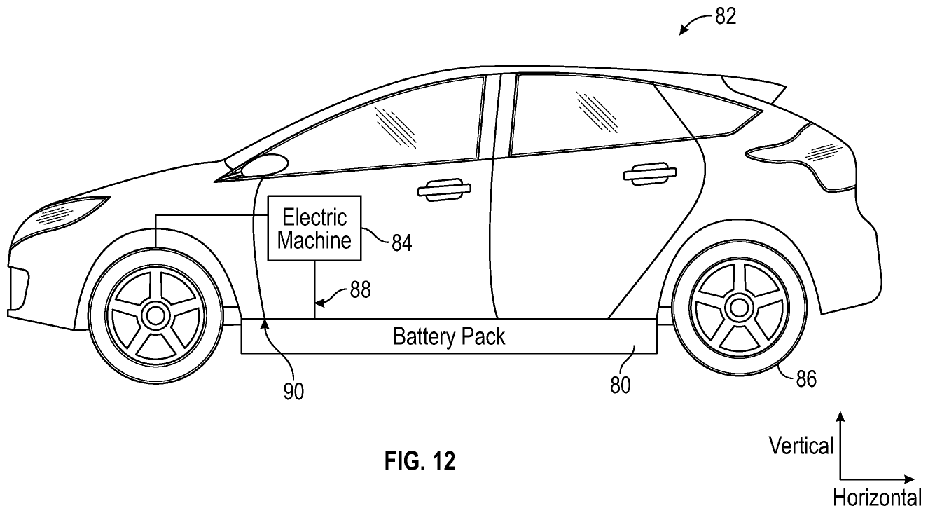

FIGS. 10, 11, and 12 illustrate an exemplary electrical component to which the electrical header assembly 10 described above may be secured. In this implementation, the electrical header assembly 10 may be mounted to a traction battery pack 80 of an electrified vehicle 82 (see FIG. 12). Again, however, other electrical components including non-automotive implementations could benefit from the designs discussed above within the scope of this disclosure.

The electrified vehicle 82 may include any type of electrified powertrain. In the illustrated embodiment, the electrified vehicle 82 is a full electric vehicle propelled solely through electric power, such as by one or more electric machines 84, without assistance from an internal combustion engine. The electric machine 84 may operate as an electric motor, an electric generator, or both. The electric machine 84 receives electrical power and can convert the electrical power to torque for driving one or more wheels 86 of the electrified vehicle 82. A voltage bus 88 may electrically couple the electric machine 84 to the traction battery pack 80.

The traction battery pack 80 may be secured to an underbody 90 of the electrified vehicle 82. However, the traction battery pack 80 could be located elsewhere on the electrified vehicle 82 within the scope of this disclosure.

The traction battery pack 80 may be a high voltage traction battery pack system that includes one or more battery arrays 92 (e.g., battery assemblies or groupings of rechargeable battery cells 94) capable of outputting electrical power to power the electric machine 84 and/or other electrical loads of the electrified vehicle 82. Other types of energy storage devices and/or output devices could alternatively or additionally be used to electrically power the electrified vehicle 82.

The battery cells 94 may be stacked side-by-side along a stack axis to construct a grouping of battery cells, sometimes referred to as a “cell stack.” In the highly schematic depiction of FIG. 11, the battery cells 94 are stacked in a direction into the page to construct each battery array 92, and thus the battery arrays 92 may extend in cross-vehicle direction. However, other configurations may also be possible. The total number of battery arrays 92 and battery cells 94 provided within the traction battery pack 80 is not intended to limit this disclosure.

In an embodiment, the battery cells 94 of each battery array 92 are prismatic, lithium-ion cells. However, battery cells having other geometries (cylindrical, pouch, etc.), other chemistries (nickel-metal hydride, lead-acid, etc.), or both could alternatively be utilized within the scope of this disclosure.

The battery arrays 92 and various other battery internal components (e.g., bussed electrical center, battery electric control module, wiring, connectors, etc.) may be housed within an interior area 96 of a sealed enclosure 12. The sealed enclosure 12 may include an enclosure cover 98 and an enclosure tray 99. The enclosure cover 98 may be secured (e.g., bolted, welded, adhered, etc.) to the enclosure tray 99 to provide the interior area 96. The size, shape, and overall configuration of the sealed enclosure 12 is not intended to limit this disclosure.

The traction battery pack 80 may include one or more of the electrical header assemblies 10. Each electrical header assembly 10 may be secured relative to the wall 48 of the sealed enclosure 12. The wall 48 may be part of the enclosure cover 98, the enclosure tray 99, or both. The exact mounting location of each electrical header assembly 10 could vary and is therefore not intended to limit this disclosure.

The exemplary electrical header assemblies of this disclosure include boltless designs that provide secure mounting to sealed enclosures without the use of bolts, screws, adhesives, etc. The proposed solutions provide for a serviceable and leak tight mounting configuration.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

What is claimed is:

1. An electrical header assembly, comprising:
an electrical header including a first mounting flange having a locking tang; and
an electrical header connector including a second mounting flange having a flared lip,
wherein the locking tang and the flared lip are configured to engage one another to secure the electrical header to the electrical header connector as the electrical header is moved into engagement with the electrical header connector.

2. The electrical header assembly as recited in claim 1, wherein the first mounting flange is disk-shaped and includes a front surface, a rear surface, and a circumferential surface that connects between the front surface and the rear surface.

3. The electrical header assembly as recited in claim 2, wherein the locking tang is formed within the circumferential surface.

4. The electrical header assembly as recited in claim 2, comprising a recess formed in the rear surface.

5. The electrical header assembly as recited in claim 4, comprising a first seal received within the recess and arranged to seal against the flared lip.

6. The electrical header assembly as recited in claim 5, comprising a second seal arranged to seal against a cylindrical body of the second mounting flange.

7. The electrical header assembly as recited in claim 1, wherein the locking tang is configured to flex outwardly to accommodate the flared lip within a slot of the first mounting flange as the electrical header is moved into further engagement with the electrical header connector.

8. The electrical header assembly as recited in claim 7, wherein the flared lip is configured to engage a cam surface of the locking tang to force the locking tang to flex outwardly.

9. The electrical header assembly as recited in claim 8, wherein the cam surface includes a lower plateau, an upper plateau, and an angled surface that connects between the lower plateau and the upper plateau.

10. The electrical header assembly as recited in claim 9, wherein the flared lip enters the slot at the lower plateau and forces the locking tang to flex further outwardly as it travels along the angled surface toward the upper plateau as the electrical header is moved into further engagement with the electrical header connector.

11. An electrical component, comprising:
a sealed enclosure;
an electrical header assembly including an electrical header and an electrical header connector configured for mounting the electrical header relative to a wall of the sealed enclosure;
the electrical header including a first mounting flange having a locking tang; and
the electrical header connector including a second mounting flange having a flared lip that can engage the locking tang to secure the electrical header to the electrical header connector as the electrical header is moved into engagement with the electrical header connector.

12. The electrical component as recited in claim 11, wherein the electrical component is a traction battery pack.

13. The electrical component as recited in claim 11, wherein the second mounting flange of the electrical header connector includes a base.

14. The electrical component as recited in claim 13, wherein the base is integrated as part of the wall of the sealed enclosure.

15. The electrical component as recited in claim 13, wherein the base is mounted to the wall by a weld.

16. The electrical component as recited in claim 11, wherein the first mounting flange is disk-shaped and includes a front surface, a rear surface, and a circumferential surface that connects between the front surface and the rear surface.

17. The electrical component as recited in claim 16, wherein the locking tang is formed within the circumferential surface.

18. The electrical component as recited in claim 16, comprising a recess formed in the rear surface, and further comprising a first seal received within the recess and arranged to seal against the flared lip.

19. The electrical component as recited in claim 18, comprising a second seal arranged to seal against a cylindrical body of the second mounting flange.

20. The electrical component as recited in claim 11, wherein the locking tang is configured to flex outwardly to accommodate the flared lip within a slot of the first mounting flange as the electrical header is moved into further engagement with the electrical header connector.
